(19) United States
(12) Patent Application Publication
(10) Pub. No.: US 2009/0096098 A1
(43) Pub. Date: Apr. 16, 2009

(54) INTER-CONNECTING STRUCTURE FOR SEMICONDUCTOR PACKAGE AND METHOD OF THE SAME

(75) Inventors: Wen-Kun Yang, Hsin-Chu City (TW); Hsien-Wen Hsu, Lujhou City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/872,164

(22) Filed: Oct. 15, 2007

(51) Int. Cl. H01L 23/488; H01L 21/44

(52) U.S. Cl. 257/738; 438/614; 257/E23.023; 257/E21.476

(57) ABSTRACT

The interconnecting structure for a semiconductor die assembly comprises a build-up layers having RDL formed therein formed over a die having die pads formed thereon, wherein the RDL is coupled to the die pads; an isolation base having ball openings attached over the build-up layer to expose ball pads within the build-up layers; and conductive balls placed into the ball openings of the isolation base and attached on the ball pads within the build-up layers.

### FIELD OF THE INVENTION

This invention relates to a semiconductor package, and more particularly to an inter-connecting structure for of package.

### DESCRIPTION OF THE PRIOR ART

The function of chip package includes power distribution, signal distribution, heat dissipation, protection and support, etc. As a semiconductor become more complicated, the traditional package technique, for example lead frame package, flex package, rigid package technique, can't meet the demand of producing smaller chip with high density elements on the chip. In general, array packaging such as Ball Grid Array (BGA) packages provide a high density of interconnects relative to the surface area of the package. Typical BGA packages include a convoluted signal path, giving rise to high impedance and an inefficient thermal path which results in poor thermal dissipation performance. With increasing package density, the spreading of heat generated by the device is increasingly important. In order to meet packaging requirements for newer generations of electronic products, efforts have been expended to create reliable, cost-effective, small, and high-performance packages. Such requirements are, for example, reductions in electrical signal propagation delays, reductions in overall component area, and broader latitude in input/output (I/O) connection pad placement. In order to meet those requirements, a WLP (wafer level package) has been developed, wherein an array of I/O terminals is distributed over the active surface, rather than peripheral-leaded package. Such distribution of terminal may increase the number of I/O terminals and improves the electrical performance of the device. Further, the area occupied by the IC with interconnections when mounted on a printed circuit board is merely the size of the chip, rather than the size of a packaging lead-frame. Thus, the size of the WLP may be made very small. One such type may refer to chipscale package (CSP).

Improvements in IC packages are driven by industry demands for increased thermal and electrical performance and decreased size and cost of manufacture. In the field of semiconductor devices, the device density is increased and the device dimension is reduced, continuously. The demand for the packaging or interconnecting techniques in such high density devices is also increased to fit the situation mentioned above. The formation of the solder bumps may be carried out by using a solder composite material. Flip-chip technology is well known in the art for electrically connecting a die to a mounting substrate such as a printed wiring board. The active surface of the die is subject to numerous electrical couplings that are usually brought to the edge of the chip. Electrical connections are deposited as terminals on the active surface of a flip-chip. The bumps include solders and/or plastics that make mechanical connections and electrical couplings to a substrate. The solder bumps after RDL have bump high around 50-100 um. The chip is inverted onto a mounting substrate with the bumps aligned to bonding pads on the mounting substrate, as shown in FIG. 1. If the bumps are solder bumps, the solder bumps on the flip-chip are soldered to the bonding pads on the substrate. Solder joints are relatively inexpensive, but exhibit increased electrical resistance as well as cracks and voids over time due to fatigue from thermo-mechanical stresses. Further, the solder is typically a tin-lead alloy and lead-based materials are becoming far less popular due to environmental concerns over disposing of toxic materials and leaching of toxic materials into ground water supplies.

Furthermore, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

U.S. Pub. No. 2004/0266162 A1 discloses a semiconductor wafer having a plurality of bonding pads and a passivation layer. The under bump metallurgy layers are formed on each of the bonding pads respectively. Then, pluralities of bumps are disposed separately in the openings wherein each of the bump structures has a bump and a reinforced layer covering the bump. Referring to FIG. 1a, the semiconductor device 200 has bonding pads 202, a passivation layer 204 exposing the bonding pads 202 and a plurality of under bump metallurgy layers 206 formed on the bonding pads 202. Solder bumps 208 are formed on the under bump metallurgy layers 206. The solder bumps 208 are covered or encompassed by bump-reinforced collars 210. U.S. Pat. No. 6,271,469 disclosed a package with RDL layer, 124 as shown in FIG. 1b. The microelectronic package includes a microelectronic die 102 having an active surface. An encapsulation material 112 is disposed adjacent the microelectronic die side(s), wherein the encapsulation material includes at least one surface substantially planar to the microelectronic die active surface. A first dielectric material layer 118 may be disposed on at least a portion of the microelectronic die active surface and the encapsulation material surface. At least one conductive trace 124 is then disposed on the first dielectric material layer 118. The conductive trace(s) 124 is in electrical contact with the microelectronic die active surface. A second dielectric layer 126 and a third dielectric layer 136 acted as solder mask layer are subsequently formed over the die. Via holes 132 are formed within the second dielectric layer 126 for coupling to the traces 124. The metal pads 134 acted as UBM function are connected to the via holes 132 and solders 138 are located on the pads. The package includes microelectronic die having an active surface and at least one side. An encapsulation material is disposed adjacent the microelectronic die side(s), wherein the encapsulation material includes at least one surface substantially planar to the microelectronic die active surface. The conductive trace(s) is in electrical contact with the microelectronic die active surface. At least one conductive trace extends vertically adjacent the microelectronic die active surface and vertically adjacent the encapsulation material surface.

Since these conventional designs include too many stacked dielectric layers, the mechanical property of the dielectric layers involves the “plastic/hardness” property instead of “elastic/softness” due to the CTE of die and molding compound in process concern; and the solder balls are just attached over the RDL, apparently, the design fails to consider the TCT (thermal cycle test), ball-shear test and drop test issues. Once the device is attached (by SMT process) on the mother board (PCB), the solder balls will be suffered the highest stress in temperature cycling due to the CTE mismatching between PCB and device itself, and either the solder mask (top dielectric layer) or bump reinforced collars can not locked the solder balls firmly (too thin and brittle—easy crack during TCT). Furthermore, the CTE of the upper dielectric layer is not matching to the CTE of PCB, it means that there is no stress releasing buffer layers to be built inside. Therefore, the scheme is not reliable during thermal cycle and the operation of the package.

Therefore, the present invention provides a solder interconnection structure with for a flip chip scheme to overcome the aforementioned problem and also provide the better device performance.

### SUMMARY OF THE INVENTION

An object of the present invention is to provide a semiconductor device package (chip assembly) with a chip and a conductive trace that provides a low cost, high performance and high reliability package.

A further object of the present invention is to provide a semiconductor device package with a high reliability during thermal cycle and operation.

Another object of the present invention is to provide a convenient, cost-effective method for manufacturing a semiconductor device package.

In one aspect, the interconnecting structure for a semiconductor die assembly, comprising a build-up layers having RDL formed therein formed over a die having die pads formed thereon, wherein the RDL is coupled to the die pads; an isolation mask (base) having ball openings (through holes) attached over the build-up layer to expose ball pads within the build-up layers; and conductive balls placed into the ball openings of the isolation mask (base) and attached on the ball pads within the build-up layers.

The structure further comprises an under bump metallurgy (UBM) structure formed over the conductive ball pads, Alternatively, the UBM attaches on sidewall of the ball openings. The structure of claim 1, wherein the RDL is formed by laminated copper foil, sputtered metal, E-plated CuNi/Au. The isolation mask is formed of epoxy, ER4, FR5 or BT. The isolation mask includes glass fiber contained therein. The structure further comprises an adhesive layer under the isolation mask (base).

The RDL is configured in the scheme of fan-in type or fan-out type. The structure further comprises a substrate formed under the die. A core paste is formed adjacent to the die.

A method of forming an interconnecting structure for a semiconductor die assembly, comprises forming build-up layers over a die or core area of wafer (or panel) form, wherein the build-up layers includes RADL formed therein; opening at least the upper layer of the build-up layers to expose the solder metal pads; attaching an isolation mask having ball openings pattern on the build-up layers and expose the solder metal pads; and placing solder balls into the ball openings of the isolating mask and attached on the solder metal pads of the build-up layers. The method further comprises a step of forming an under bump metallurgy (UBM) over the solder ball pads.

### BRIEF DESCRIPTION OF THE DRAWINGS

FIG. 1a and FIG. 1b are cross-sectional views showing a semiconductor chip assembly in accordance with prior art.

FIG. 2 is cross-sectional views showing a semiconductor chip assembly in accordance with embodiment of the present invention.

FIG. 3 illustrates a cross section view showing semiconductor chip assembly in accordance with embodiment of the present invention.

FIG. 4 illustrates a cross section view showing semiconductor chip assembly in accordance with embodiment of the present invention.

FIG. 5 illustrates a cross section view showing semiconductor chip assembly in accordance with further embodiment of the present invention.

FIGS. 6a-6c illustrate a cross section view showing semiconductor chip assembly in accordance with embodiment of the present invention.

FIG. 7 illustrates a cross section view showing semiconductor chip assembly mounted on a motherboard in accordance with embodiment of the present invention.

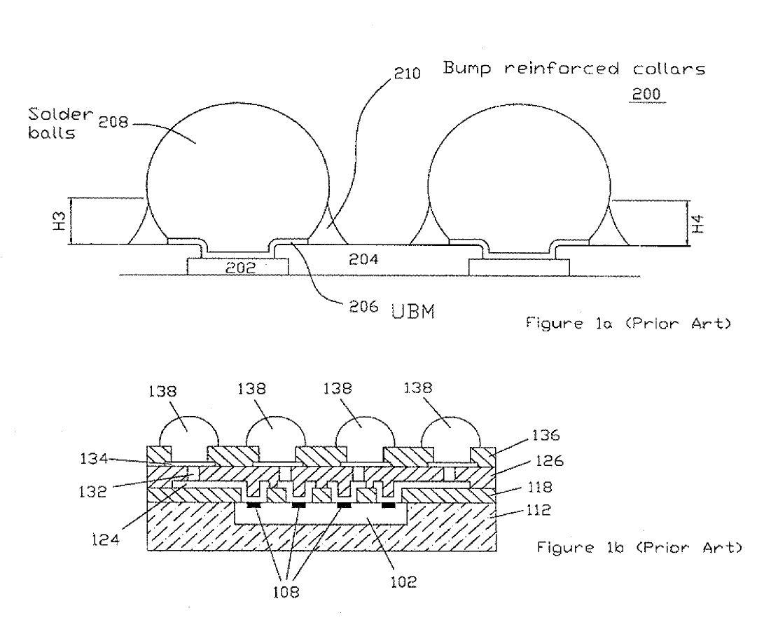

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying claims.

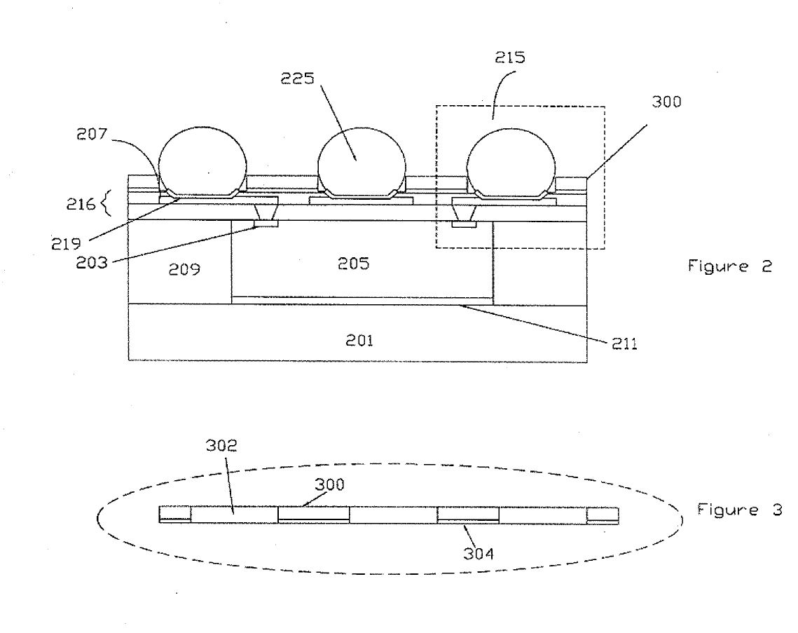

The present invention discloses a semiconductor device package structure. The present invention provide a semiconductor chip assembly which includes chip, conductive trace and metal inter-connecting as shown in FIG. 2.

FIG. 2 is cross-sectional view of a substrate 201. The substrate 201 could be a metal, alloy, silicon, glass, ceramic, plastic, PCB or PI. The thickness of the substrate is around 40-200 micron-meters. It could be a single or multi-layer substrate. A chip 205 is adhesion on the surface by an adhesive material 211. It could have the elastic properties to absorb the stress generated by thermal. The interconnecting structures (detail will be described below) 215 are coupled to the pads 203 of the chip 205. The pads 203 could be Al, Cu pads or other metal pads. A stacked build-up scheme 216 is formed over the die 205 and the core paste 209 which is formed adjacent to the die 205 for protection. The build-up layer scheme 216 also includes openings for exposing the pads 203. RDL (re-distribution layer) 207 is formed within the stacked build-up scheme 216. It is noted that partial of the RDL 207 is exposed by the stacked build-up scheme 216 for receiving the conductive balls 225. The conductive bumps 225 are coupled to the RDL 207.

An isolation base (or mask) 300 with bump (all) openings 302 as shown in FIGS. 2 and 3 are formed over the stacked build-up scheme 216. The bump openings 302 are aligned to the aforementioned openings of the stacked build-up scheme 216. For example, the isolation base 300 is composed of epoxy FR4/FR5, BT, preferably, it is BT base with fiber glass formed therein. In one case, the isolation mask 300 includes adhesive layer 304 formed on the lower surface. Under bump metallurgy (UBM) 219 is formed over the solder ball pads coupled to the RDL 207.

The RDL 207 is formed by an electroplating, plating or etching method. The copper (and/or nickel) electroplating operation continues until the copper layer has the desired thickness. Conductive layers extend out of the area for receiving chip. It refers to fan-out scheme. The core paste 209 encapsulated the die 205 and over the substrate 200. It can be formed by resin, compound, silicon rubber or epoxy.

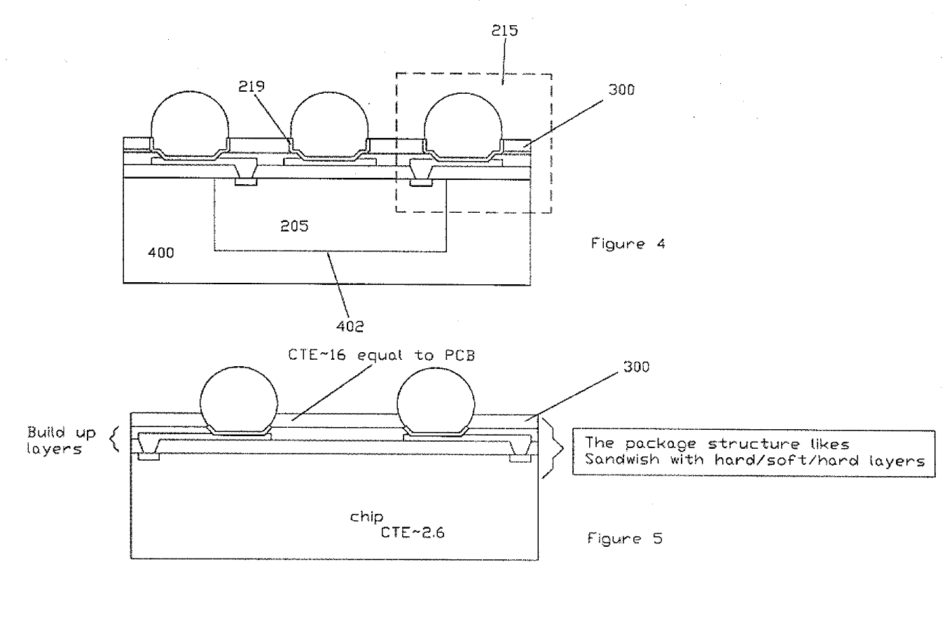

In FIG. 4 shows alternative embodiment of the present invention. Most of the structure is similar to the embodiment of above, except the substrate structure. Please refer to FIG. 4, the substrate 400 includes a cavity (or through-hole) 402 to receive the die 205. Alternative, the invention can be applied to a fan-in scheme as shown in FIG. 5. The RDL 502 does not extend out of the die area, conversely, the RDL 502 towards the center area of the die 205 from the pads 504 located periphery of the die 205. The lower surface and side surface of the die 502 is exposed and the dimension is also reduced. This is a true WL-CSP. Both of the embodiments include the isolating mask (or base) having ball openings formed thereon. The thickness of the substrate is significant reduced and it may provide better thermal dissipation scheme than conventional.

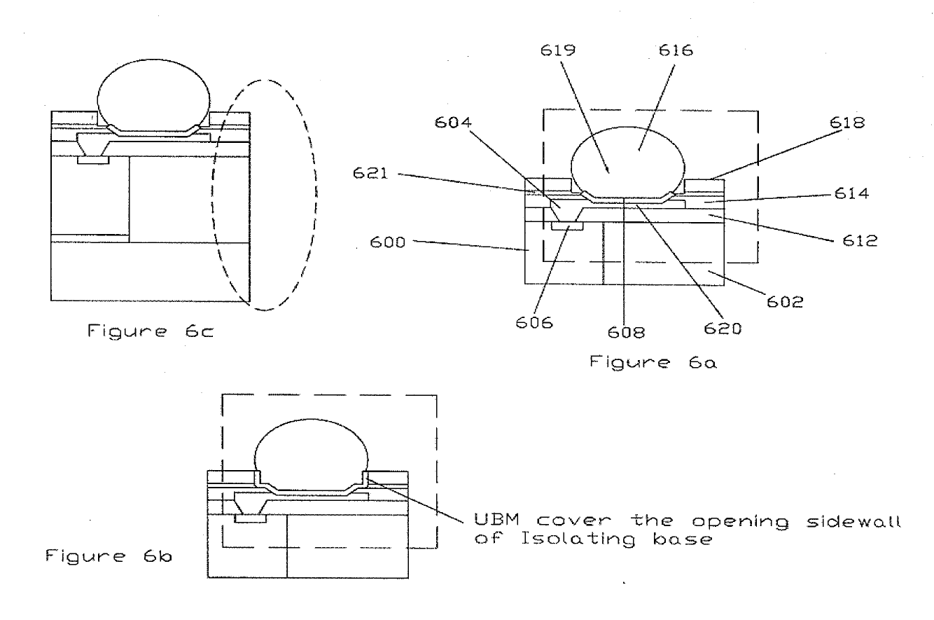

Please refer to FIG. 6a, it shows the interconnection structure which includes a stacked build-up layers having at least one lower dielectric layer 612 and an upper layer 614 stacked over the die 600 and the core 602. A conductive layer 604 is refilled into the openings of the stacked build-up layer and coupled to the pads 606 of the die 600. An isolating mask 618 having ball openings is formed on the stacked build-up layers. The adhesive layer 621 is formed under the isolation mask 618. The ball opening 619 is exposed at least partial of solder ball pads which are coupled to the RDL. The area 620 to receive the ball 616 is referred to the solder metal pad 620 which is aligned to the ball opening of the isolating mask 618. The metal is formed on the top of the solder metal pad 620 and within the lower portion of the ball opening is called under bump metallurgy (UBM) 608 to receive the ball as the barrier and adhesion for preventing the issue between the ball and the ball pad. The composition of under bump metallurgy can be copper, nickel, gold etc.; in principle, the solder tin with nickel will construct the Inter Metallurgy Compound (IMC) during higher temperature, and it can avoid the electron migration in copper area. Generally, in comparison with other metal area, the area of IMC will be crack, easily, while the IMC is impacted by external or outside force.

Turning to FIGS. 6b and 6c, it shows that the UBM covers the sidewall of the ball opening of the isolation mask 618. Another example is that the isolation mask has an adhesive layer 621 formed under the mask. The sidewall and edge (indicated by dot close loop in FIG. 6c) of package be protected to prevent the build up layer, balls, core or silicon from being damaged during handling by external or outside force (Ex. by tweezers) since the isolating base has flexible property due to fiber glass inside.

A method of forming an interconnecting structure for a semiconductor die assembly, comprises the steps of forming build-up layers over a die or core area of wafer (or panel) form, wherein the build-up layers includes RDL formed therein. The next step is to open at least the upper layer of the build-up layers to expose the solder metal pads; followed by attaching an isolation mask having ball openings pattern on the build-up layers and expose the solder metal pads. A placement of solder balls is performed to form the balls into the ball openings of the isolating mask and attached on the solder metal pads of the build-up layers. The method further comprises a step of forming an under bump metallurgy (UBM) over the solder ball pads.

Next, after the solder ball placement is finished, IR re-flow steps are performed to form the final terminal. Lately, wafer or panel level final testing is introduced and cutting the dice or core paste to singulate wafer into the individual packages. The present invention offers simple process than conventional method.

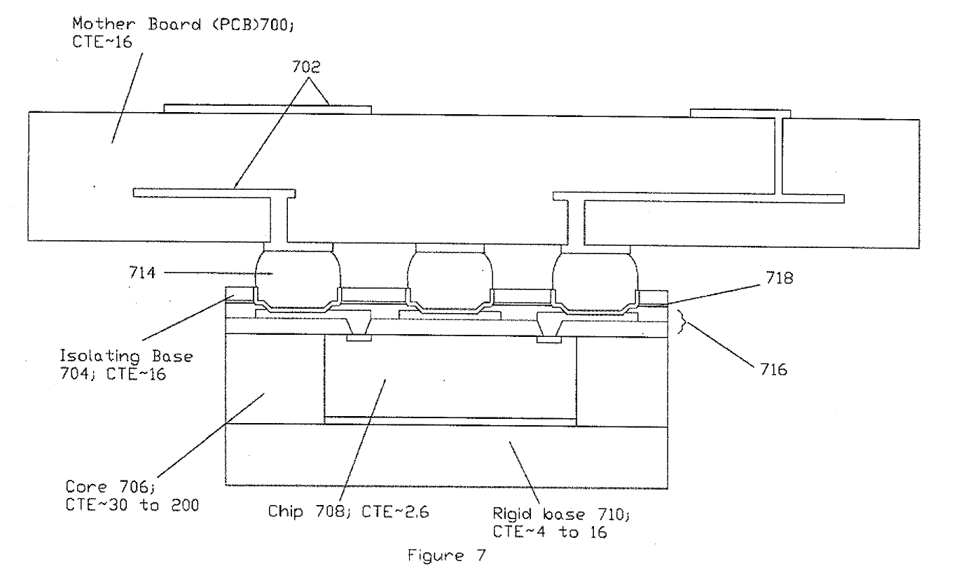

Please refer to FIG. 7, it shows the assembly which mounted on the motherboard. The motherboard 700 includes circuit traces 702 on both side surfaces and within the motherboard. The circuit traces are introduced to for electrical communication between devices. The illustration indicates the CTE of each major elements of the present invention. For example, the CTE of the motherboard (PCB) 700 is around CTE˜16; the CTE of the isolation base or mask 704 is around CTE˜16; the CTEs of the core paste 706, die 708, rigid base (substrate) 710 are respectively, around 30˜200, 2.6, 4-16. The solder ball/bumps 714 are stress free due to the same CTE between PCB 700 and the isolating base 704 and the balls 714 are all locked in the openings of the isolating base (mask) 704. The build up layer 716 with elastic property acts as buffer area to release thermal stress by conductive line structure, it means the build up layers 716 will absorb the thermal mechanical stress between the die/core and isolating base/solder balls due to the elastic property of build up layers 716. The adhesion layer 718 with rubber elastic property can also absorb the thermal stress, thereby solving the CTE mismatching issue. In the other application, the adhesion layer 718 can be used to replace (act as) the upper dielectric layer of build up layers 718.

The advantages and benefits of the present invention include:

Enhanced the strength of solder balls/bumps: the present invention provides better reliability in TCT (temperature cycling test), drop test, ball shear test due to the solder balls are strongly locked on the pocket (hole) of isolating mask (base) and the CTE of isolating mask (base) is matching with CTE of print circuit board (PCB), and the build up layers with elastic/elongation property can absorb the thermal mechanical stress during temperature cycling.

Enhanced the strength of top side and sidewall of wafer level package for both fan-in type and fan-out type: Since the isolating mask (base) has fiber glass inside, the strength of isolating base (BT/FR5/FR4/ . . . ) is great than the top dielectric layer, so, it can prevent the build up layers from being damaged during the external force, especially in package edge area.

Easy process to form the solder balls/bumps: The ball pads area becomes “pocket” after form the isolating base on top the build up layers, the depth of hole will be around 60 um to 150 um (depends on the ball diameters), so, the balls can easy to fall into the “pocket” during placement the ball into metal pads.

Easy to replace the solder balls/bumps—rework: The top of build up layer becomes strong after the formation of the isolating base on the top, consequently, the normal rework procedure of solder balls will not damage the top surface of package.

The present invention provides the sandwich structure from the cross section point of view, the mechanical properties of the semiconductor device according to the present invention are: the upper layer with flexible/hardness property and having fiber glass inside; the mediate layer with elastic/elongation/softness property (build up layers); and the lower layer with rigid/plastic/hardness property (die/substrate). The sandwich structure can provide better reliability in thermal mechanical stress test.

Although preferred embodiments of the present invention has been described, it will be understood by those skilled in the art that the present invention should not be limited to the described preferred embodiment. Rather, various changes and modifications can be made within the spirit and scope of the present invention, as defined by the following claims.

Having described the invention, the following is claimed:

1. An interconnecting structure for a semiconductor die assembly, comprising:
a build-up layers having RDL formed therein formed over a die having die pads formed thereon, wherein said RDL is coupled to said die pads;
an isolation base having bump openings attached over said build-up layer to expose ball pads within said build-up layers; and
a conductive bumps placed into said bump openings of said isolation base and attached on said ball pads within said build-up layers.

2. The structure of claim 1, further comprising an under bump metallurgy (UBM) structure formed over said conductive ball pads.

3. The structure of claim 2, wherein said UBM attaches on sidewall of said bump openings.

4. The structure of claim 1 wherein said RDL is formed by laminated copper foil, sputtered metal, E-plated Cu/Ni/Au.

5. The structure of claim 1, wherein said isolation base is formed of epoxy, ER4, FR5 or ET.

6. The structure of claim 5, wherein said isolation base includes glass fiber contained therein.

7. The structure of claim 1, further comprising an adhesive layer under said isolation base.

8. The structure of claim 1, wherein said RDL is configured in the scheme of fan-in type.

9. The structure of claim 1, wherein said RDL is configured in the scheme of fan-out type.

10. The structure of claim 1, further comprising a substrate formed under said die.

11. The structure of claim 10, further comprising core paste formed adjacent to said die.

12. A method of forming an interconnecting structure for a semiconductor die assembly, comprising:
forming build-up layers over a die or core area of wafer (or panel) form, wherein said build-up layers includes RDL formed therein;
opening at least upper layer of the build-up layers to expose the solder metal pads;
attaching an isolation base having bump openings pattern on said build-up layers and expose said solder metal pads; and
placing solder bumps into said bump openings of said isolating base and attached on said solder metal pads of said build-up layers.

13. The method of claim 12, further comprising a step of forming an under bump metallurgy (UBM) over said solder bump pads.

14. The method of claim 13, wherein said UBM attaches on sidewall of said bump openings.

15. The method of claim 12, wherein said RDL is formed by laminated copper foil, sputtered metal, E-plated Cu/Ni/Au.

16. The method of claim 12, wherein said isolation base is formed of epoxy, ER4, FR5 or BT.

17. The method of claim 16, wherein said isolation base includes glass fiber contained therein.

18. The method of claim 12, further comprising an adhesive layer under said isolation base.

19. The method of claim 12, wherein said RDL is configured in the scheme of fan-in type or fan-out type.

20. The method of claim 12, further comprising a substrate formed under said die.

21. The method of claim 12, further comprising a step of performing IR re-flow process.
